(19) United States
(12) Patent Application Publication
(10) Pub. No.: US 2024/0266858 A1
(43) Pub. Date: Aug. 8, 2024

(54) METHOD OF ACTIVE CHARGING CONTROL AND DEVICE THEREOF

(71) Applicant: SIMPLO TECHNOLOGY CO., LTD., Hsinchu County (TW)

(72) Inventor: Shu-Hung YEH, Hsinchu County (TW)

(73) Assignee: SIMPLO TECHNOLOGY CO., LTD., Hsinchu County (TW)

(21) Appl. No.: 18/344,228

(22) Filed: Jun. 29, 2023

(30) Foreign Application Priority Data
Feb. 7, 2023 (TW) 112104290

(51) Int. Cl. H02J 7/00; G01R 31/36; G01R 31/387

(52) U.S. Cl. CPC H02J 7/00712; G01R 31/3648; G01R 31/387

(57) ABSTRACT

A method of active charging control and a device thereof are provided, in which a target capacity value of a battery pack is obtained according to a target cycle count of the battery pack, and a calculated capacity value is calculated according to the plurality of updated capacity values of the battery pack and their corresponding plurality of weight values. Thereby, a capacity difference adjustment value is calculated based on the target capacity value and the calculated capacity value, so that a battery charging device can actively adjust the charging voltage of the battery pack according to the capacity difference adjustment value. Therefore, the requirement of actively controlling the charging voltage of the battery pack can be achieved, thereby optimizing the performance of the battery pack and improving the service life.

### BACKGROUND

### 1. Technical Field

The present disclosure relates to an active charging control technology, and more particularly, to a method of active charging control and control device thereof.

### 2. Description of Related Art

Nowadays, since electronic devices such as notebooks, tablets, phones, smart watches and the like are widely used in daily life, and with the development of science and technology, users' demand for electronic devices is also continuously increasing, thus battery service life has become extremely important.

Currently, in order to improve battery service life of electronic devices, battery charging adjustments are mostly performed according to known conditional thresholds, such as cycle counts, high voltage time and the like. However, these conditions can only be adjusted for charging under fixed conditions and thresholds, and state adjustments in real time cannot be achieved.

Therefore, how to optimize the performance of the battery and meet the requirements of long cycle and long service life of the battery, and how to greatly improve the competitiveness of the products and satisfy the user's need when the performance of the battery is optimized, have become urgent issues in the industry to be solved.

### SUMMARY

In order to solve the aforementioned conventional technical problems or provide related effects, the present disclosure provides a method of active charging control, the method comprises: obtaining a target capacity value of a battery pack according to a target cycle count of the battery pack; obtaining a plurality of updated capacity values of the battery pack and their corresponding cycle counts; calculating a plurality of weight values corresponding to the plurality of updated capacity values of the battery pack according to the target cycle count and the cycle counts corresponding to the plurality of updated capacity values; calculating a calculated capacity value of the battery pack according to the plurality of updated capacity values of the battery pack and their corresponding plurality of weight values; and calculating a capacity difference adjustment value according to the target capacity value and the calculated capacity value, so that a battery charging device actively adjusts a charging voltage of the battery pack according to the capacity difference adjustment value.

In the aforementioned embodiment, the method further comprises: obtaining the target capacity value of the battery pack according to a target capacity value graph of battery service life and the target cycle count of the battery pack.

In the aforementioned embodiment, the method further comprises: calculating a capacity difference value of the battery pack according to the target capacity value and the calculated capacity value; and judging whether the capacity difference value is greater than a threshold value, such that the capacity difference adjustment value is calculated when the capacity difference value is greater than the threshold value.

In the aforementioned embodiment, one of the plurality of weight values corresponding to the latter one of the plurality of updated capacity values is greater than another one of the plurality of weight values corresponding to the former one of the plurality of updated capacity values.

In the aforementioned embodiment, the method further comprises: calculating a cycle count compensation value corresponding to the plurality of updated capacity values according to a compensation factor combined with the target cycle count and the cycle counts corresponding to the plurality of updated capacity values, so as to calculate the plurality of weight values.

In the aforementioned embodiment, the method further comprises: converting the capacity difference adjustment value into the charging voltage of the battery pack via the battery charging device according to a proportional relationship.

The present disclosure further provides an active charging control device, which comprises: a battery pack including at least one battery; a measuring device electrically connected to the battery pack to sequentially measure a plurality of updated capacity values of the battery pack; a register communicatively connected to the measuring device to sequentially record the plurality of updated capacity values measured by the measuring device; and a processor communicatively connected to the battery pack, the measuring device and the register, wherein the processor counts cycle counts corresponding to the plurality of updated capacity values to perform the aforementioned method of active charging control.

In the aforementioned embodiment, the measuring device is controlled by the processor to measure the plurality of updated capacity values of the battery pack periodically or according to a set condition.

In the aforementioned embodiment, the register stores a target capacity value graph related to battery service life of the battery pack.

In the aforementioned embodiment, the active charging control device further comprises a communication component communicatively connected to the processor to transfer a capacity difference adjustment value of the battery pack to the battery charging device.

As can be seen from the above, in the method of active charging control and device thereof, after obtaining the target capacity value corresponding to the cycle count of the battery pack, the latest plurality of updated capacity values of the battery pack are further obtained, and a plurality of weight values corresponding to the plurality of updated capacity values are calculated, so that the capacity difference value between the calculated capacity value and the target capacity value and its capacity difference adjustment value can be calculated. Hence, by using the capacity difference adjustment value of the battery pack, the charging voltage of the battery pack can be actively controlled, thereby optimizing the performance of the battery pack and achieving the requirements of long cycle and long service life of the battery pack.

### BRIEF DESCRIPTION OF THE DRAWINGS

FIG. 1 is a schematic view of a framework of an active charging control device according to the present disclosure.

FIG. 2 is a target capacity value graph of service life of a battery.

FIG. 3 is a flowchart illustrating a method of active charging control according to the present disclosure.

### DETAILED DESCRIPTION

The following describes the implementation of the present disclosure with examples. Those skilled in the art can easily understand other advantages and effects of the present disclosure from the content disclosed in this specification.

It should be understood that, the structures, ratios, sizes and the like in the accompanying figures are used for illustrative purposes to facilitate the perusal and comprehension of the content disclosed in the present specification by one skilled in the art, rather than to limit the conditions for practicing the present disclosure. Any modification of the structures, alteration of the ratio relationships, or adjustment of the sizes without affecting the possible effects and achievable proposes should still be deemed as falling within the scope defined by the technical content disclosed in the present specification. Meanwhile, terms such as “one,” “first,” “second,” “above,” “below” and the like are merely used for clear explanation rather than limiting the practicable scope of the present disclosure, and thus, alterations or adjustments of the relative relationships thereof without essentially altering the technical content should still be considered in the practicable scope of the present disclosure.

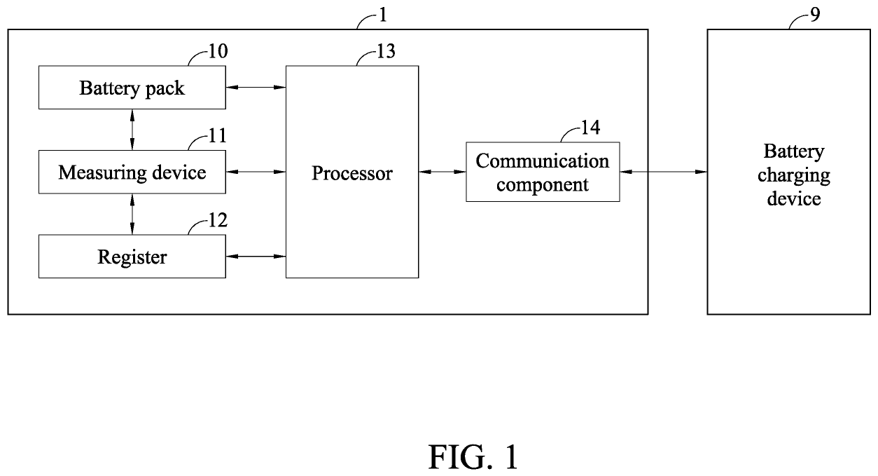

FIG. 1 is a schematic view of a framework of an active charging control device 1 according to the present disclosure. As shown in FIG. 1, the active charging control device 1 comprises: at least one (such as one or more) battery pack 10, a measuring device 11, a register 12, a processor 13, and a communication component 14.

The battery pack 10 comprises at least one (such as one or more) battery, wherein batteries included in the battery pack 10 can be nickel-cadmium (Ni—Cd) batteries, nickel-metal hydride (Ni-MH) batteries, or lithium ion (Li-Ion) batteries, and the like. However, the battery types and battery combinations in the battery pack 10 are not limited to as such.

The measuring device 11 can be a battery capacity tester, or can be composed of an ammeter, a voltmeter, or a wattmeter, and the measuring device 11 is electrically connected to the battery pack 10. The processor 13 controls the measuring device 11, so that the measuring device 11 measures a plurality of updated capacity values (or known as utilized capacity updated values) of the battery pack 10 periodically (such as every minute or every 250 milliseconds) or according to a set condition (such as when the battery pack 10 is powered off).

The register 12 can be a component such as a hard drive (a mechanical drive or a solid state drive) or a memory card and the like and is communicatively connected (or electrically connected) to the measuring device 11, so as to record the plurality of updated capacity values of the battery pack 10 measured by the measuring device 11 in time sequence.

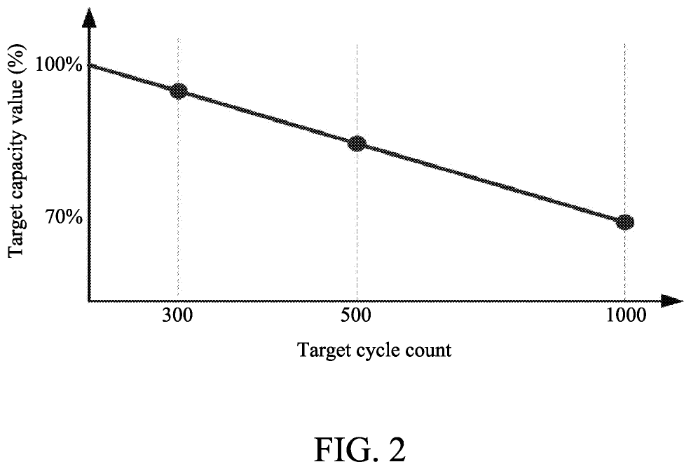

In an embodiment, as shown in FIG. 2, the register 12 further stores a target capacity value graph related to the battery service life of the battery pack 10. It should be noted that the target capacity value graph of the battery service life is a relationship between the target capacity values (or known as design capacity [DC]) and target cycle count, where the graph of the target capacity values of the battery service life indicates the percentage value of the expected target capacity value corresponding to a certain cycle counts of charging of the battery that have been reached.

The processor 13 can be an electronic equipment with suitable computing mechanism such as a central processing unit (CPU), a microprocessor, a single-chip microcomputer and the like, and the processor 13 is communicatively connected (or electrically connected) to the battery pack 10, the measuring device 11 and the register 12 to count the cycle count of the battery pack 10 and perform an active charging control algorithm, so as to calculate a capacity difference adjustment value of the battery pack 10.

The communication component 14 can be a system management bus (SMBus) and is communicatively connected (or electrically connected) to the processor 13 to transfer the capacity difference adjustment value of the battery pack 10 to a battery charging device 9, so that the battery charging device 9 can adjust the charging voltage of the battery pack 10 according to the capacity difference adjustment value. In another embodiment, the battery charging device 9 is composed of at least one charging circuit, another register and another processor and is electrically connected to the battery pack 10 to charge the battery pack 10. However, the design of the battery charging device 9 is not limited to as such.

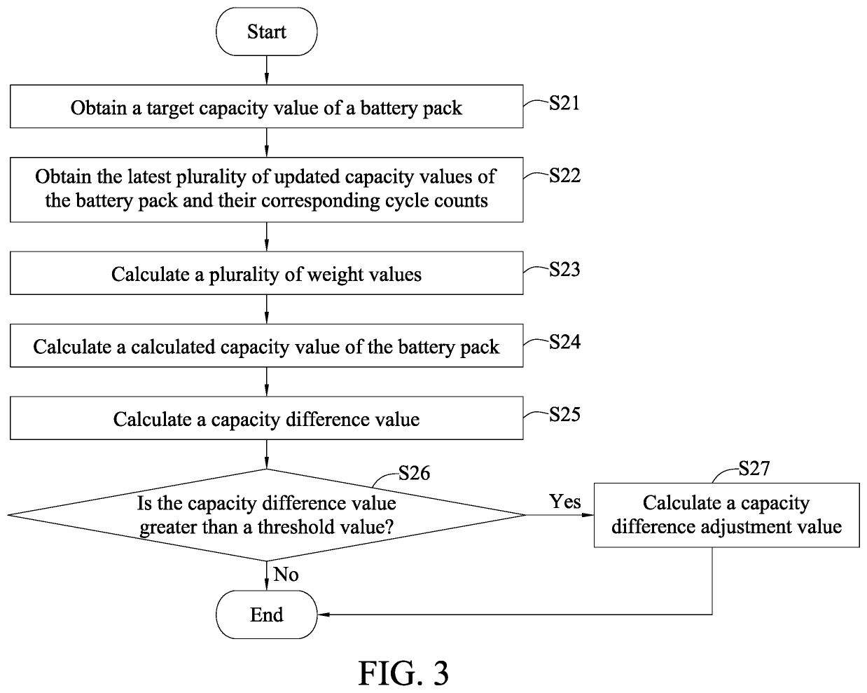

FIG. 3 is a flowchart illustrating a method of active charging control according to the present disclosure, wherein the method of active charging control adopts an active charging control algorithm to perform charging control of the battery. Further, FIG. 3 is illustrated with reference to FIG. 1, and the method of active charging control comprises the following steps S21 to S27.

In step S21, the processor 13 obtains a target capacity value of the battery pack 10 according to a target capacity value graph of the battery service life and a target cycle count of charging of the battery pack 10.

In step S22, the processor 13 obtains the latest plurality of updated capacity values and their corresponding cycle counts of the battery pack 10 from the register 12.

In step S23, the processor 13 calculates a plurality of weight values of the plurality of updated capacity values according to the target cycle count and the cycle count corresponding to the plurality of updated capacity values.

In step S24, the processor 13 calculates a calculated capacity value of the battery pack 10 according to the plurality of updated capacity values of the battery pack 10 and their corresponding plurality of weight values.

In step S25, the processor 13 calculates a capacity difference value according to the calculated capacity value and the target capacity value of the battery pack 10.

In step S26, the processor 13 compares whether the capacity difference value of the battery pack 10 is greater than a threshold value, wherein if the capacity difference value is greater than the threshold value, then step S27 is performed; otherwise, if the capacity difference value is less than or equal to the threshold value, then the processor 13 ends its task.

In step S27, the processor 13 calculates the capacity difference adjustment value of the battery pack 10 for the battery charging device 9 to adjust the charging voltage of the battery pack 10 according to the capacity difference adjustment value.

The following is an implementation aspect of the active charging control device 1 performing the active charging control, and FIG. 1 to FIG. 3 are referred together for illustration. On the other hand, the same content between this implementation aspect and the above illustration will not be repeated.

In an embodiment, the processor 13 obtains a target capacity value T of the battery pack 10 according to the target capacity value graph (as shown in FIG. 2) of the battery service life in the register 12 and the target cycle count (CC_{Target}) of charging of the battery pack 10. Then, the processor 13 obtains the latest plurality of updated capacity values X(n) of the battery pack 10 and their corresponding cycle count (CC(n)) from the register 12, wherein the plurality of updated capacity values X(n) are measured periodically (such as every minute) or according to a set condition (such as when the battery pack 10 is powered off) by the measuring device 11 controlled by the processor 13, and the processor 13 counts the cycle count (CC(n)) corresponding to the plurality of updated capacity values X(n).

Moreover, the processor 13 calculates the plurality of weight values W(n) corresponding to the plurality of updated capacity values X(n) by a weight formula (1), wherein the weight formula (1) is as follows:

$$W ( n ) = H ( n ) \times {CC}_{comp} ( n ) \qquad ( 1 )$$

$$H ( n ) = 2 \hat{} [ ( n ) - ( {base}_{num} ) ] \qquad ( 1 ‐ 1 )$$

$${CC}_{comp} ( n ) = 2 \hat{} ( \frac{{CC}_{target}}{{CC}_{Factor} - CC ( n )} ) \qquad ( 1 ‐ 2 )$$

Wherein W(n) is the weight value of the plurality of updated capacity values, wherein n is 0˜N, N is any positive integer; H(n) is the time compensation value of the plurality of updated capacity values, so that baseₙᵤₘ is used to adjust the weight value of each updated capacity value under its cycle count, wherein 0≤ baseₙᵤₘ<N, and Nis any positive integer; CC_{comp}(n) is the cycle count compensation value corresponding to the plurality of updated capacity values, and is used to compensate the next updated capacity value when the previous updated capacity value is missing; CC_{Target} is the target cycle count; CC_{Factor} is the cycle count compensation factor used to limit the maximum value of CC_{comp}(n) to adjust the influence of the weight value under different cycle counts; and CC(n) is the cycle count corresponding to a plurality of updated capacity values. In an embodiment, the cycle count compensation value CC_{comp}(n) corresponding to the plurality of updated capacity values is calculated via the cycle count compensation factor CC_{Factor}, the target cycle count CC_{Target}, and the cycle count CC(n) corresponding to the plurality of updated capacity values. In specific, in consideration of time factor, the weight formula (1) raises the weight of the latest updated capacity value X(n), so that the subsequent calculated capacity value Y(CC_{Target}) can be close to the actual capacity of the battery pack 10.

Afterward, the processor 13 calculates a calculated capacity value Y(CC_{Target}) of the battery pack 10 according to the plurality of updated capacity values X(n) and their corresponding plurality of weight values W(n) with a weighted average formula (2), wherein the weighted average formula (2) is as follows:

$$Y ( C {C}_{T a r g e t} ) = \frac{X ( 0 ) W ( 0 ) + X ( 1 ) W ( 1 ) + … + X ( n ) W ( n )}{( W ( 0 ) + W ( 1 ) + … + W ( n ) )} \qquad ( 2 )$$

Thereby, the processor 13 calculates a capacity difference value E between the target capacity value T and the calculated capacity value Y(CC_{Target}). Further, when the capacity difference value E is greater than a threshold value, the processor 13 calculates a capacity difference adjustment value Cap_{adj} by using an adjustment value formula (3), wherein the formula (3) is as follows:

$$C a {p}_{a d j} = \frac{T - Y ( C {C}_{Target} )}{T} \times 100 \% \qquad ( 3 )$$

Finally, the capacity difference adjustment value Cap_{adj} calculated by the processor 13 is provided to the battery charging device 9 via the communication component 14, so that the battery charging device 9 adjusts the charging voltage of the battery pack 10 according to the capacity difference adjustment value Cap_{adj}.

The following first embodiment and second embodiment are applied embodiments of the present disclosure, and FIG. 1 to FIG. 3 are referred together for illustration. In addition, the same content between these embodiments and the above illustration will not be repeated.

In the first embodiment, the processor 13 compares the percentage value (90%) of a first target capacity value T of the battery pack 10 from a target capacity value graph (as shown in FIG. 2) of the battery service life according to a first target cycle count (target cycle count=300), and then the processor 13 multiplies the design capacity (3000 mAh) of the battery pack 10 by the percentage value (90%) to obtain the first target capacity value T (2700 mAh). In other words, the expected service life of the battery pack 10 is that its capacity must be greater than or equal to 2700 mAh under 300 cycle counts.

Then, the processor 13 obtains the last three updated capacity values and their corresponding cycle counts from the register 12 in time sequence, such as a first updated capacity value X(0)=2700 mAh and its corresponding cycle count CC(n=0)=296, a second updated capacity value X(1)=2600 mAh and its corresponding cycle count CC(n=1)=298, a third updated capacity value X(2)=2650 mAh and its corresponding cycle count CC(n=2)=300, wherein the first updated capacity value X(0) is the oldest updated data, and the third updated capacity value X(2) is the latest updated data.

Afterward, the processor 13 calculates the first weight value W(0), the second weight value W(1) and the third weight value W(2) corresponding to the first updated capacity value X(0), the second updated capacity value X(1) and the third updated capacity value X(2) by a weight formula (1).

Specifically, assuming that n=0˜2, baseₙᵤₘ=0, first target cycle count CC_{Target}=300, first compensation factor CC_{Factor}=500, wherein the first weight value

$$W ( n = 0 ) = H ( 0 ) \times C {C}_{c o m p} ( 0 ) = ( {2}^{0 - 0} \times {2}^{\frac{300}{500 - 29 ó}} ) = 2.771 ,$$

the second weight value

$$W ( n = 1 ) = H ( 1 ) \times C {C}_{c o m p} ( 1 ) = ( {2}^{1 - 0} \times {2}^{\frac{300}{500 - 298}} ) = 5.598 ,$$

and the third weight value

$$W ( n = 2 ) = H ( 2 ) \times C {C}_{c o m p} ( 2 ) = ( {2}^{2 - 0} \times {2}^{\frac{300}{500 - 300}} ) = 11.313 .$$

It should be noted that the weight value of the newer updated capacity value can be greater than the weight value of the older updated capacity value by the weight formula (1). Furthermore, when the capacity of the battery pack 10 is actually updated, the processor 13 may count the cycle count but not update the capacity value. For instance, the aforementioned cycle count CC(0) of the first updated capacity value X(0) is 296, and the cycle count CC(1) of the second updated capacity value X(1) is 298, thus the updated capacity value when the cycle count is 297 is missing between both of them, thereby the first compensation factor CC_{Factor} can amplify the second weight value W(1) of the second updated capacity value X(1) to compensate the missing updated capacity value.

Accordingly, the processor 13 calculates a first calculated capacity value Y(CC_{Target}=300) of the battery pack 10 according to the first updated capacity value X(0), the second updated capacity value X(1) and the third updated capacity value X(2) and their corresponding first weight value W(0), second weight value W(1) and third weight value W(2) with a weighted average formula (2). Specifically, the first calculated capacity value Y(300)=(2700×2.771+2600×5.598+2650×11.313)/(2.771+5.598+11.313)≤2643 mAh.

Therefore, a first capacity difference value E(2700 mAh-2643 mAh=57 mAh) between the first target capacity value T and the first calculated capacity value Y(300) is calculated by the processor 13, and the first capacity difference value E=57 mAh is greater than a threshold value (such as 50 mAh). For this, the processor 13 calculates a first capacity difference adjustment value Cap_{adj} by an adjustment value formula (3). In specific, the first capacity difference adjustment value Cap_{adj}=(2700 mAh-2643 mAh)/2700 mAh×100%=2.11%.

Finally, the first capacity difference adjustment value Cap_{adj} calculated by the processor 13 is provided to the battery charging device 9 via the communication component 14, such that the battery charging device 9 adjusts the charging voltage of the battery pack 10 according to the first capacity difference adjustment value Cap_{adj}. For example, the battery charging device 9 adjusts the charging voltage according to the first capacity difference adjustment value Cap_{adj}=2.11%. For instance, the battery charging device 9 is set as dropping 10 mV/cell charging voltage per 1% of the first capacity difference adjustment value Cap_{adj}, thus the battery charging device 9 calculates the dropping 20 mV/cell charging voltage of the battery pack 10 according to the first capacity difference adjustment value Cap_{adj}=2.11% (and the first decimal place of the first capacity difference adjustment value Cap_{adj} is rounded off), so as to adjust the charging voltage.

In the second embodiment, the processor 13 compares the percentage value (80%) of a second target capacity value T of the battery pack 10 from a target capacity value graph (as shown in FIG. 2) of the battery service life according to a second target cycle count (target cycle count=500), and then the processor 13 multiplies the design capacity (3000 mAh) of the battery pack 10 by the percentage value (80%) to obtain the second target capacity value T (2400 mAh). In other words, the expected service life of the battery pack 10 is that its capacity must be greater than or equal to 2400 mAh under 500 cycle counts.

Then, the processor 13 obtains the last five updated capacity values and their corresponding cycle counts from the register 12 in time sequence, such as a fourth updated capacity value X(0)=2400 mAh and its corresponding cycle count CC(n=0)=420, a fifth updated capacity value X(1)=2300 mAh and its corresponding cycle count CC(n=1)=440, a sixth updated capacity value X(2)=2350 mAh and its corresponding cycle counts CC(n=2)=460, a seventh updated capacity value X(3)=2350 mAh and its corresponding cycle counts CC(n=3)=480, an eighth updated capacity value X(4)=2300 mAh and its corresponding cycle counts CC(n=4)=500, wherein the fourth updated capacity value X(0) is the oldest updated data, and the eighth updated capacity value X(4) is the latest updated data.

Afterward, the processor 13 calculates the fourth weight value W(0), the fifth weight value W(1), the sixth weight value W(2), the seventh weight value W(3) and the eighth weight value W(4) corresponding to the fourth updated capacity value X(0), the fifth updated capacity value X(1), the sixth updated capacity value X(2), the seventh updated capacity value X(3) and the eighth updated capacity value X(4) by the weight formula (1).

Specifically, assuming that n=0˜4, baseₙᵤₘ=1, second target cycle count CC_{Target}=500, second compensation factor CC_{Factor}=800, wherein the fourth weight value

$$W ( n = 0 ) = H ( 0 ) \times C {C}_{c o m p} ( 0 ) = ( 1 \times {2}^{\frac{500}{800 - 420}} ) = 2.489$$

(since the minimum of H(n) must be 1, thus H(0)=1); the fifth weight value

$$W ( n = 1 ) = H ( 1 ) \times C {C}_{c o m p} ( 1 ) = ( {2}^{1 - 1} \times {2}^{\frac{500}{800 - 440}} ) = 2 \text{.618}$$

the sixth weight value

$$W ( n = 2 ) = H ( 2 ) \times C {C}_{c o m p} ( 2 ) = ( {2}^{2 - 1} \times {2}^{\frac{500}{800 - 4 ó 0}} ) = 5.5 \; 42 ;$$

the seventh weight value

$$W ( n = 3 ) = H ( 3 ) \times C {C}_{c o m p} ( 3 ) = ( {2}^{3 - 1} \times {2}^{\frac{500}{800 - 480}} ) = 11.814 ;$$

and the eighth weight value

$$W ( n = 4 ) = H ( 4 ) \times C {C}_{c o m p} ( 4 ) = ( {2}^{4 - 1} \times {2}^{\frac{500}{800 - 500}} ) = 25.3 98.$$

Accordingly, the processor 13 calculates a second calculated capacity value Y(CC_{Target}=500) of the battery pack 10 according to the fourth updated capacity value X(0), the fifth updated capacity value X(1), the sixth updated capacity value X(2), the seventh updated capacity value X(3) and the eighth updated capacity value X(4) and their corresponding fourth weight value W(0), fifth weight value W(1), sixth weight value W(2), seventh weight value W(3) and eighth weight value W(4) with the weighted average formula (2). Specifically, the second calculated capacity value Y(500)=(2400×2.489+2300×2.618+2350×5.542+2350×11.814+2300×25.398)/(2.489+2.618+5.542+11.814+25.398)≤2323 mAh.

Therefore, a second capacity difference value E(2400 mAh-2323 mAh=77 mAh) between the second target capacity value T and the second calculated capacity value Y(500) is calculated by the processor 13, and the second capacity difference value E=77 mAh is greater than the threshold value (such as 50 mAh). For this, the processor 13 calculates the first capacity difference adjustment value Cap_{adj} by the first adjustment formula (3). In specific, the second capacity difference adjustment value Cap_{adj}=(2400 mAh-2323 mAh)/2400 mAh×100%=3.208%.

Afterward, the second capacity difference adjustment value Cap_{adj} calculated by the processor 13 is provided to the battery charging device 9 via the communication component 14, such that the battery charging device 9 adjusts the charging voltage of the battery pack 10 according to the second capacity difference adjustment value Cap_{adj}. For example, the battery charging device 9 adjusts the charging voltage according to the second capacity difference adjustment value Cap_{adj}=3.208%. For instance, the battery charging device 9 is set as dropping 10 mV/cell charging voltage per 1% of the second capacity difference adjustment value Cap_{adj}, thus the battery charging device 9 calculates the dropping 30 mV/cell charging voltage of the battery pack 10 according to the second capacity difference adjustment value Cap_{adj}=3.208% (and the first decimal place of the second capacity difference adjustment value Cap_{adj} is rounded off), so as to adjust the charging voltage.

To sum up, in the method of active charging control and device thereof of the present disclosure, after obtaining the target capacity value corresponding to the cycle count of the battery pack, the latest plurality of updated capacity values of the battery pack are further obtained, and a plurality of weight values corresponding to the plurality of updated capacity values are calculated, so that the capacity difference value between the calculated capacity value and the target capacity value and its capacity difference adjustment value can be calculated. Hence, by using the capacity difference adjustment value of the battery pack, the charging voltage of the battery pack can be actively controlled, thereby optimizing the performance of the battery pack and achieving the requirements of long cycle and long service life of the battery pack.

Therefore, the present disclosure further has the following technical features and effects thereof:

1. Compared to the prior art that can only adjust the charging voltage in fixed conditions and thresholds, the present disclosure can use the target capacity of the battery service life and the current actual useable capacity state (i.e., the updated capacity value), and adjust the charging voltage in real time in a feedback manner, so as to achieve the application purpose of long cycle and long service life of the battery.

2. The present disclosure takes the time factor into consideration at the same time to calculate weight values according to time relationship via weight formulas, so that the weight of the latest updated capacity value is raised, such that the calculated capacity value can be close to the current actual capacity of the battery pack, thereby improving the accuracy of adjusting the charging voltage.

The foregoing embodiments are provided for the purpose of illustrating the principles and effects of the present disclosure, rather than limiting the present disclosure. Anyone skilled in the art can modify and alter the above embodiments without departing from the spirit and scope of the present disclosure. Therefore, the scope of protection with regard to the present disclosure should be as defined in the accompanying claims listed below.

What is claimed is:

1. A method of active charging control, comprising:
obtaining a target capacity value of a battery pack according to a target cycle count of the battery pack;
obtaining a plurality of updated capacity values of the battery pack and their corresponding cycle counts;
calculating a plurality of weight values corresponding to the plurality of updated capacity values of the battery pack according to the target cycle count and the cycle counts corresponding to the plurality of updated capacity values;
calculating a calculated capacity value of the battery pack according to the plurality of updated capacity values of the battery pack and their corresponding plurality of weight values; and
calculating a capacity difference adjustment value according to the target capacity value and the calculated capacity value, so that a battery charging device actively adjusts a charging voltage of the battery pack according to the capacity difference adjustment value.

2. The method of claim 1, further comprising obtaining the target capacity value of the battery pack according to a target capacity value graph of battery service life and the target cycle count of the battery pack.

3. The method of claim 1, further comprising:
calculating a capacity difference value of the battery pack according to the target capacity value and the calculated capacity value; and
judging whether the capacity difference value is greater than a threshold value, such that the capacity difference adjustment value is calculated when the capacity difference value is greater than the threshold value.

4. The method of claim 1, wherein one of the plurality of weight values corresponding to the latter one of the plurality of updated capacity values is greater than another one of the plurality of weight values corresponding to the former one of the plurality of updated capacity values.

5. The method of claim 1, further comprising calculating a cycle count compensation value corresponding to the plurality of updated capacity values according to a compensation factor combined with the target cycle count and the cycle counts corresponding to the plurality of updated capacity values, so as to calculate the plurality of weight values.

6. The method of claim 1, further comprising converting the capacity difference adjustment value into the charging voltage of the battery pack via the battery charging device according to a proportional relationship.

7. An active charging control device, comprising:
a battery pack including at least one battery;
a measuring device electrically connected to the battery pack to sequentially measure a plurality of updated capacity values of the battery pack;
a register communicatively connected to the measuring device to sequentially record the plurality of updated capacity values measured by the measuring device; and
a processor communicatively connected to the battery pack, the measuring device and the register, wherein the processor counts cycle counts corresponding to the plurality of updated capacity values to perform the method of claim 1.

8. The active charging control device of claim 7, wherein the measuring device is controlled by the processor to measure the plurality of updated capacity values of the battery pack periodically or according to a set condition.

9. The active charging control device of claim 7, wherein the register stores a target capacity value graph related to battery service life of the battery pack.

10. The active charging control device of claim 7, further comprising a communication component communicatively connected to the processor to transfer a capacity difference adjustment value of the battery pack to the battery charging device.
